(19) United States
(12) Patent Application Publication
(10) Pub. No.: US 2024/0194826 A1
(43) Pub. Date: Jun. 13, 2024

(54) STRESS-STRAIN ENGINEERING OF SEMICONDUCTOR MEMBRANES

(71) Applicant: University of Surrey, Guildford (GB)

(72) Inventors: Steven Clowes, Guildford (GB); David Cox, Guildford (GB); Mateus Masteghin, Guildford (GB); Stephen Sweeney, Guildford (GB)

(21) Appl. No.: 18/555,504

(22) PCT Filed: Apr. 19, 2022
(86) PCT No.: PCT/GB2022/050981

§ 371 Date: Oct. 13, 2023

(30) Foreign Application Priority Data
Apr. 19, 2021 (GB) 2105585.0

(51) Int. Cl. H01L 33/16; H01L 33/00; H01L 33/34

(52) U.S. Cl. CPC H01L 33/16; H01L 33/005; H01L 33/34

(57) ABSTRACT

A semiconductor structure comprising: a semiconductor membrane, the semiconductor membrane having at least one amorphised area and an active area wherein the at least one amorphised area is adjacent the active area such that the at least one amorphised area exerts strain on the active area and a method of introducing strain into a crystalline semiconductor membrane by ion implantation.

### FIELD

The present invention is concerned with semiconductor membranes, and methods of manufacturing and straining the semiconductor membranes.

### BACKGROUND

There are many benefits of strain in semiconductor device engineering. Strained silicon devices offer an alternative to III-V high-electron-mobility-transistors (HEMTs) that is compatible with existing industry processes. The mobility of Si nMOSFETs under 1% tensile strain is increased by up to 15% and even up to 40% in Si thin film transistors under 0.584% strain.^{1,2} These benefits arise because silicon has six-fold (Δ6) conduction band degeneracy, and under strain this splits into a two-fold (Δ2) and a four-fold (Δ4) set, with an energy gap between Δ2 and Δ4 that depends on the amount of strain.^{3,4} Splitting Δ6 causes a reduction in electron scattering in n-type which both increases mobility and decreases noise and heating effects.⁴ Moreover, strain also splits the light-holes (LH) and heavy-holes (HH) in the valence bands, further reducing scattering in p-type.³ The splitting of the degeneracy of the heavy and light hole bands increases the efficiency of III-V based semiconductor lasers. Strain can also change indirect-bandgap semiconductors to direct-gap, and control the emission probability and gain. Almost all current optoelectronic emitters (e.g. lasers, LEDs) are based on compound semiconductors (typically, III-V based) owing to their direct band gap which gives rise to high optical efficiencies. However, these are significantly more expensive to produce than silicon based electronic devices. Silicon would therefore be preferable for optical emitters but is fundamentally hindered by its indirect band gap. If they could be realised, silicon-compatible direct band-gap semiconductors would produce a step-change in the utilisation of optoelectronic/photonic devices due to the compatibility with the drive electronics in complementary metal-oxide-semiconductor (CMOS).⁵ Accordingly, there is a need for an improved method of producing strained silicon and germanium. The present invention arises from the inventors' work in this field.

### SUMMARY

In accordance with a first aspect of the invention, there is provided a semiconductor structure comprising:
a semiconductor membrane, wherein the semiconductor membrane has at least one amorphised area and an active area, wherein the at least one amorphised area is adjacent the active area such that the at least one amorphised area exerts strain on the active area.

The semiconductor membrane may define a thickness of at least 1 nm, at least 5 nm or at least 10 nm, more preferably of at least 15 nm, at least 20 nm or at least 25 nm and most preferably of at least 30 nm. The semiconductor membrane may define a thickness of less than 100 μm, less than 10 μm or less than 1 μm, more preferably less than 100 nm, less than 70 nm or less than 50 nm, and most preferably less than 40 nm. The semiconductor membrane may define a thickness of between 1 nm and 100 μm, between 5 nm and 10 μm or between 10 nm and 1 μm, more preferably between 15 and 100 nm, between 20 and 70 nm or between 25 and 50 nm, and most preferably between 30 and 40 nm.

Preferably, the semiconductor membrane comprises a surface layer and a subsurface layer, wherein the surface layer comprises the active area and the at least one amorphised area, and the subsurface layer is crystalline.

The semiconductor membrane may have a length and/or width of at least 10 μm, more preferably at least 25 μm, at least 50 μm or at least 75 μm, and most preferably at least 100 μm. The semiconductor membrane may have a length and/or width of less than 250 μm, more preferably less than 200 μm, less than 175 μm or less than 150 μm, most preferably less than 125 μm. The semiconductor membrane may have a length and/or width of between 10 and 250 μm, more preferably between 25 and 200 μm, between 50 and 175 μm or between 75 and 150 μm, and most preferably between 100 and 125 μm.

The semiconductor membrane may be disposed on or in a supporting structure. The semiconductor membrane may be secured to the supporting structure. The semiconductor membrane may define a window in a larger semiconductor structure. The larger semiconductor structure may be a wafer. For instance, the window may have been exposed in the structure due to etching. The etching may be dry etching, wet etching, plasma etching or reactive ion etching.

Advantageously, the semiconductor membrane exhibits bi-material bowing where the semiconductor membrane has been amorphised.

The thickness of the surface layer may be between 5 and 95% of the thickness of the semiconductor membrane, more preferably between 10 and 90%, between 20 and 80% or between 30 and 70% of the thickness of the semiconductor membrane, and most preferably between 40 and 60% or between 45 and 55% of the thickness of the semiconductor membrane. In preferred embodiment, the thickness of the surface layer is about 50% of the thickness of the semiconductor membrane.

In one embodiment, the active area surrounds a first amorphised area. Accordingly, the first amorphised area may have a substantially circular shape. Alternatively, the first amorphised area may have an elongated shape.

The semiconductor membrane may have a second amorphised area. The second amorphised area may surround the active area. Accordingly, the active area may comprise or define an annulus between the first and second amorphised areas.

However, in a preferred embodiment, the at least one amorphised area surrounds a first active area.

Accordingly, the at least one amorphised area may comprise or define an annulus and the first active area may be located in the centre of the annulus.

The first active area may have a substantially circular shape. Alternatively, the first active area may have an elongated shape.

In embodiments where the first active area has an elongate shape, the elongate shape may define an aspect ratio of between 150:1 and 2:1, between 100:1 and 3:1 or between 75:1 and 4:1, more preferably between 50:1 and 5:1, between 40:1 and 6:1 or between 30:1 and 8:1, most preferably between 25:1 and 10:1. The inventors have produced semiconductor structures with an elongate shape with aspect ratios of 125 μm:5 μm, 100 μm:5 μm and 50 μm:5 μm, and not that they all produce similar results. The inventors note that aspect ratio of 25 μm:5 μm produce more strain but might cause bending in the central region. The inventors also note that any length longer than 50 μm and width lower than 5 μm generates high uniaxial strain.

The ratio between the maximum width of the amorphised area and the maximum width of the first active area may be at least 1:50, more preferably at least 1:25, at least 1:10, at least 1:5, at least 1:1, at least 2:1 or at least 5:1, and most preferably at least 10:1. The ratio between the maximum width of the amorphised area and the maximum width of the first active area may be between 1:50 and 200:1, more preferably between 1:25 and 100:1, between 1:10 and 75:1, between 1:5 and 50:1, between 1:1 and 40:1, between 2:1 and 30:1 or between 5:1 and 20:1 most preferably between 10:1 and 15:1. The inventors have shown that a small non-exposed region at the centre of a large membrane produces higher biaxial strain.

The active area may have a maximum width of less than 1,000 μm, less than 750 μm, less than 500 μm, less than 250 μm, less than 200 μm, less than 150 μm, less than 100 μm, less than 75 μm, less than 50 μm, less than 40 μm, less than 30 μm, less than 20 μm, less than 10 μm or less than 5 μm. The active area may have a maximum width of at least 0.1 μm, at least 0.5 μm, at least 1 μm, at least 1.5 μm, at least 2 μm, at least 2.5 μm, at least 5 μm, at least 10 μm, at least 20 μm, at least 30 μm or at least 40 μm. The active area may have a maximum width between 0.1 and 1,000 μm, between 1 and 750 μm, between 1.5 and 500 μm or between 2 and 250 μm. In some embodiments, the active area may have a maximum width between 2.5 and 200 μm, between 5 and 150 μm, between 10 and 100 μm, between 20 and 75 μm or between 40 and 50 μm. In alternative embodiments, the active area may have a maximum width between 0.1 and 30 μm, between 0.5 and 20 μm, between 1 and 15 μm, between 1.5 and 10 μm, between 2 and 7.5 μm or between 2.5 and 5 μm.

The semiconductor membrane may comprise a plurality of active areas. Each active area may have a circular or an elongate shape. Preferably, each active area has an elongate shape. The semiconductor membrane may comprise one amorphised area. The one amorphised area may surround and separate all of the active areas. Alternatively, the semiconductor membrane may comprise a plurality of amorphised areas. Accordingly, each amorphised area may surround a corresponding active area.

In semiconductor science, when discussing the groups of the periodic table, traditional names are used. In this specification, the boron group (i.e. the group where boron is the first element) is referred to as group III. Similarly, the carbon group (i.e. the group where carbon is the first element) is referred to as group IV, the nitrogen group (i.e. the group where nitrogen is the first element) is referred to as group V and the fluorine group (i.e. the group where fluorine is the first element) is referred to as group VII. These groups may alternatively be referred to as groups 13, 14, 15 and 17.

The semiconductor membrane may comprise or consist of a group IV element, a III-V compound semiconductor or a group IV alloy. The group IV element may be silicon or germanium. It may be appreciated that a III-V compound semiconductor may be an alloy containing elements from groups III and V in the periodic table. Examples of III-V compound semiconductors include GaAs, GaP, GaN, GaSb, GaBi, InN, InAs, InP, InSb, InBi, AlN, AlAs, AlP AlSb, AlBi. It may be appreciated that a group IV alloy may be an alloy containing elements from group IV in the periodic table. Examples of group IV alloys include SiGe, GeSn and SiGeSn.

The semiconductor membrane may comprise a heterostructure. Accordingly, the membrane may comprise two or more layers of a group IV element, a III-V compound semiconductor and/or a group IV alloy. The heterostructure may include quantum wells.

In some embodiments, the semiconductor membrane comprises a group IV element or a group IV alloy. Accordingly, the semiconductor membrane may comprise or consist of silicon, germanium or silicon-germanium.

The semiconductor membrane may comprise a doping species. The semiconductor may be n-doped or p-doped. The doping species can be a transition metal and/or a group III to group VII element. The transition metal may be erbium. The group III to group VII element may be boron, aluminium, gallium, indium, phosphorous, bismuth, germanium, silicon, antimony, arsenic or tin. In some embodiments, the group III to group VII element is boron, phosphorous, antimony or arsenic.

In one embodiment, the doping species may be present at a concentration of less than 20 at. %, less than 15 at %, less than 10 at. % or less than 7.5 at. %, most preferably less than 5 at. %. The doping species may be present at a concentration of at least 0.1 at. %, at least 0.5 at %, at least 1 at. % or at least 2 at. %, most preferably at least 3 at. %. The doping species may be present at a concentration of between 0.1 and 20 at. %, between 0.5 and 15 at %, between 1 and 10 at. % or between 2 and 7.5 at. %, most preferably between 3 and 5 at. %. In this embodiment, the doping species is preferably from group IV or V, and most preferably tin.

In an alternative embodiment, the doping species may be present at a level of less than 1 part per 100, less than 1 part per 1,000, less than 1 part per 5,000 or less than 1 part per 10,000. The doping species may be present at a level of at least 1 part per 1,000,000, at least 1 part per 500,000, at least 1 part per 100,000 or at least 1 part per 50,000. The doping species may be present at a level of between 1 part per 100 and 1 part per 1,000,000, between 1 part per 1,000 and 1 part per 500,000, between 1 part per 5,000 and 1 part per 100,000 or between 1 part per 10,000 and 1 part per 50,000. In this embodiment, the doping species is preferably a group III to group VII element.

Accordingly, both the surface layer and the subsurface layer may comprise or consist of silicon or germanium. Similarly, both the active area and the at least one amorphised area may comprise or consist of silicon or germanium.

Preferably, the active area defines a crystalline structure. In some embodiments, the crystalline structure may be orientated such that anisotropy is exhibited in the surface plane of the active area of the crystalline structure.

In embodiments where the semiconductor is silicon and the active area has an elongated shape, a long edge of the elongated shape may be aligned with the [110], [100] or [120] crystal direction in a (100) wafer. A long edge of the elongated shape may be aligned at an angle of between 0 and 90° to the [110] direction, more preferably at an angle between 10 and 80°, between 20 and 70° or between 30 and 60°, and most preferably at an angle between 40 and 50° or at an angle of 45° to the [110] direction. Anisotropy should also be expected in a (110) Si wafer.

The membrane may comprise a resonant cavity therein. The resonant cavity may be a photonic crystal cavity or comprise one or more distributed Bragg reflectors.

The active area may have a strain of at least 0.01%, at least 0.1%, at least 0.5%, at least 1%, at least 2%, at least 3%, at least 4%, at least 5%, at least 6%, at least 7% or at least 8%. The active area may have a strain of between 0.01 and 50%, between 0.1 and 40%, between 0.5 and 30%, between 1 and 25%, between 2 and 20%, between 3 and 18%, between 4 and 16%, between 5 and 14%, between 6 and 12%, between 7 and 10% or between 8% and 9%. The strain may be measured in the centre of the active area. The magnitude of the strain may be measured based upon a shift in the Raman spectrum.

In accordance with a second aspect, there is provided a silicon on insulator substrate comprising the semiconductor structure of the first aspect.

In accordance with a third aspect, there is provided a semiconductor device comprising the semiconductor structure of the first aspect.

In accordance with a fourth aspect, there is provided an optical amplifier, an optoelectronic device, a photodetector, a photoemitter or a photonic integrated circuit comprising the semiconductor structure of the first aspect. The photonic integrated circuit may comprise both one or more photodetectors and one or more emitters provided on the same membrane.

The optical amplifier may be a laser.

The optoelectronic device may be an optoelectronic emitter. The optoelectronic emitter may be a laser diode or a light emitting diode.

The active area may have a strain of at least 0.5%, at least 1%, at least 2%, at least 3%, at least 4%, at least 5%, at least 6%, at least 7% or at least 8%. The active area may have a strain of between 0.5 and 50%, between 1 and 25%, between 2 and 20%, between 3 and 18%, between 4 and 16%, between 5 and 14%, between 6 and 12%, between 7 and % or between 8% and 9%. The strain may be measured in the centre of the active area. The magnitude of the strain may be measured based upon a shift in the Raman spectrum.

In accordance with a fifth aspect, there is provided a method of introducing strain into a crystalline semiconductor membrane comprising:
providing a crystalline semiconductor membrane,
defining at least one implantation area and at least an active area adjacent to at least one implantation area on the surface of the semiconductor membrane, and
implanting ions into the at least one implantation area of the semiconductor membrane such that the semiconductor membrane becomes amorphised in the at least one implantation area causing strain in the active area.

It may be understood that ions are not implanted into the active area.

Preferably, the method of the fifth aspect provides the semiconductor membrane of the first aspect.

It may be appreciated that implanting ions amorphises the crystalline semiconductor membrane. Accordingly, the shape and location of the at least one implantation area of the fifth aspect may correspond to the shape and location of the at least one amorphised area, as defined in relation to the first aspect. Similarly, the shape and location of the at least one active area of the fifth aspect may correspond to the shape of the at one active area defined in relation to the first aspect.

Any suitable ion may be used. Preferably, the ions have an atomic number of at least 5, at least 10, at least 20, at least 30, at least 40 or at least 50. The ions may be group III ions, group IV ions, group V ions or noble gas ions. Noble gas ions may be understood to include helium ions, neon ions, argon ions, krypton ions and xenon ions. Group III ions may be gallium ions. Group IV ions may be silicon ions or germanium ions. Doubly ionised atomic species may be used.

In some embodiments, the ions used are ions of the material comprising the semiconductor membrane. Accordingly, if the semiconductor membrane comprises or consists of silicon then silicon ions may be used. Similarly, if the semiconductor membrane comprises or consists of germanium then germanium ions may be used. However, in a preferred embodiment, the ions are noble gas ions. Preferably, the ions are xenon ions.

The semiconductor membrane may comprise or consist of silicon, germanium, silicon-germanium, doped silicon or doped germanium. The semiconductor membrane may be as defined in relation to the first aspect.

Providing the crystalline semiconductor membrane preferably comprises providing a single-crystal silicon membrane.

The method may comprise implanting ions into the at least one implantation area to a depth of between 5 and 95% of the thickness of the semiconductor membrane, more preferably between 10 and 90%, between 20 and 80% or between 30 and 70% of the thickness of the semiconductor membrane, and most preferably between 40 and 60% or between 45 and 55% of the thickness of the semiconductor membrane. In preferred embodiment, the method comprises implanting ions into the at least one implantation area to a depth of about 50% of the thickness of the semiconductor membrane.

Implanting ions may comprise exposing the surface of the implantation area to a beam of ions. It may be appreciated that the energy of the beam of ions may be varied depending upon a number of variables including the ions being used, the semiconductor being used, the thickness of the semiconductor layer and the desired depth of implantation.

Implanting ions may comprise using electron beam or optical lithography and a broad-beam implanter. Advantageously, this enables the method to be scalable.

In some embodiments, the ion beam may have an energy of at least 1 keV, at least 5 keV, or at least 10 keV, more preferably at least 15 keV, at least 20 keV or at least 25 keV. The ion beam may have an energy of between 1 keV and 1,000 keV, between 5 keV and 500 keV or between 10 and 100 keV, and more preferably between 15 and 50 keV, between 20 and 40 keV or between 25 and 35 keV.

The method may comprise a preliminary step of providing a semiconductor membrane. Providing a semiconductor membrane may comprise exposing a semiconductor membrane in a larger semiconductor structure. The larger semiconductor structure may be a wafer. The method may comprise etching a portion of the larger semiconductor structure to expose the semiconductor membrane. The etching may be dry etching, wet etching, plasma etching or reactive ion etching.

The method may comprise producing a resonant cavity in the membrane. The resonant cavity may be produced prior to implanting ions into the at least one implantation areas.

All features described herein (including any accompanying claims, abstract and drawings), and/or all of the steps of any method or process so disclosed, may be combined with any of the above aspects in any combination, except combinations where at least some of such features and/or steps are mutually exclusive.

### BRIEF DESCRIPTION OF THE FIGURES

For a better understanding of the invention, and to show how embodiments of the same may be carried into effect, reference will now be made, by way of example, to the accompanying Figures, in which:

FIG. 1a is a scanning transmission electron microscopy (STEM) image showing how irregular a silicon nano-membrane can be when produced by back-etching a silicon-on-insulator (SOI) wafer; FIG. 1b is a STEM image after exposing a 20 m width annulus (lighter region) around a 100 μm circle to a 30 keV Xe⁺ beam with an ion fluence of 3.75×10¹⁴ ion cm⁻². The central Si region became flat after the tensile strain caused by the ion beam exposure; and FIG. 1c shows a diffraction pattern collected at the central region of FIG. 1b) marked with a red coloured square. This diffraction pattern was obtained by rocking the electron beam with different angles regarding the sample normal, while collecting the diffracted signal with a diode positioned underneath the sample (transmitted through the membrane thickness). The Kikuchi pattern is similar to the expected for a silicon (001) surface, showing that the strained part of the silicon membrane remains crystalline after exposing its surrounding to the ion beam;

FIG. 2 provides STEM images of thin Si films exposed to different Xe⁺ ion beam closes and patterns. In particular, in FIG. 2a an annulus pattern exposure amorphised a region around a large crystalline Si circle, which is flat. The exposed region is the lighter region around the darker circle. The exposure consisted of 3.75×10¹⁴ ion cm². After the STEM image in FIG. 2a was taken, a smaller circle was exposed inside the remaining crystalline Si area (which then become an annulus) to doses of 1.88×10¹⁴ ions cm⁻² s⁻¹ for (b) 2 sec, (c) 4 sec, (d) 6 sec, (e) 8 sec, and (f) 9 sec. It is possible to see wrinkles being generated radially with intensity proportional to the exposure dose, i.e., by increasing the dosing at the inner circle its shrinkage applied larger tensile forces to the edges of the non-exposed area;

FIG. 3a shows a schematic drawing of a silicon membrane used for the experiments reported below. The top part of (a) shows the 3 mm diameter wafer containing 9 windows of about 110 μm×110 μm with a thickness of 35 nm. The bottom part of (a) displays how the annular patterned exposure happened, i.e., the light blue region was exposed to the ion beam leaving a small inner circle unexposed; and FIG. 3b is a plot showing how the biaxial strain obtained at the inner unexposed circle (crystalline region) can be tunned by changing its diameter. It has been noted that exposing a larger area neighbouring an unexposed crystal results in higher values of strain, which is an indication of the amplification effect obtained by both the material bowing and simply geometric factors;

FIG. 4 provides schematic drawings of the slots used in the experiments carried out to test the effect of silicon anisotropy on the resulting strains. The outer part corresponds to the exposed region of the membrane while the inner part represents the crystalline slot left at the centre. All the slots are 50 μm×5 μm, but positioned in three different orientations, being (a) at [100] direction, (b) [120] direction, and (c) [100] direction. The [110] is oriented parallel to the window frame sides while the [100] is oriented across the edges, i.e., 45° regards the [110] direction. The inset of (c) shows a scanning transmission electron microscopy (STEM) image of the 50 μm×5 μm at <100>. The bottom part of this Figure shows the Raman spectrums collected at the centre of the slot, for all orientations. The uniaxial strain values calculated are displayed within the graphs; and

FIG. 5 presents schematic drawings of the slots used in the experiments carried out to test the effect of silicon anisotropy on the resulting strains. The outer part corresponds to the exposed region of the membrane while the inner part represents the crystalline slot left at the centre. All the slots are positioned along the [100] direction but having different dimensions of (a) 50 μm×5 μm, (b) 50 μm×10 μm, and (c) 50 μm×20 μm. The bottom part of this Figure shows the Raman spectrums collected at the centre of the slots. The uniaxial strain values calculated are displayed within the graphs.

### EXAMPLE 1: WRINKLES ANNIHILATION IN BUCKLED MEMBRANES

Silicon (Si) membranes are usually prepared by wet etching a silicon-on-insulator (SOI) wafer. The top (100) silicon layer was thinned until 35 nm using reactive ion etching (RIE).⁶ The first etching consists of a back potassium hydroxide (KOH) etching to remove the bottom silicon layer, being the silicon dioxide (SiO₂) a natural stopper. The anisotropic wet etching of silicon by KOH resulted in silicon membrane windows of about 120×120 m² in which the direction along the edges is [110] and the diagonal of the squares are aligned to the [100] direction. Once the SiO₂ layer is exposed, a hydrofluoric acid (HF) etching takes place, leaving only the remaining top Si membrane.

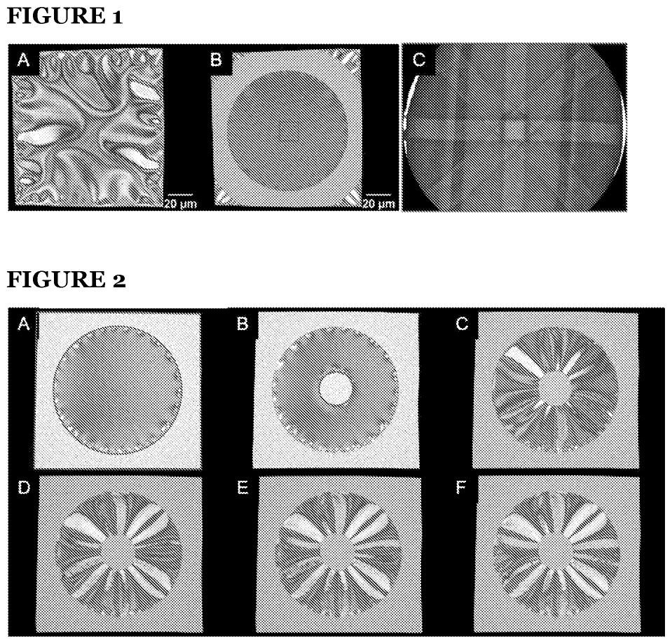

Silicon dioxide (SiO₂) layer biaxially strains the Si active layer after the expansion silicon undergoes during the oxidation, and especially due to the different thermal expansion coefficients.⁷⁻⁹ The crystalline structure is maintained by London′ weak interactions between atoms in both cells. However, during the back etch of a silicon-on-insulator (SOI) substrate to create free-standing Si membranes, the strained Si atoms reorganize to its equilibrium condition which causes buckling (visible as large wrinkles on the pristine membrane when STEM (scanning transmission electron microscopy) imaged, FIG. 1a. This buckling prevents the application of these single-crystal Si membranes as TEM grids. Moreover, a wrinkled membrane prevents future device processing such as lithographic techniques.

By exposing a 20 μm wide annulus (lighter region in FIG. 1b) around a 100 m diameter circle, one can see a flattening of the central region (FIG. 1b). The ion exposure was carried out using single-charged xenon ions (Xe⁺) at 30 keV acceleration energy at a dose of 3.75×10¹⁴ ion cm², being this ion fluence equals to the silicon full amorphization dose upon 30 keV Xe⁺ ions exposure.

A scanning electron diffraction pattern was obtained by rocking the electron beam around a given point at the centre of the flattened region (red square in in FIG. 1b), as shown in FIG. 1c. The Kikuchi lines pattern corresponds to the Si (100) and shows that after tensile straining the central region the active Si crystal remains crystalline, but now presenting long range order.

The flattening of the membrane as shown in FIG. 1 (or wrinkles annihilation in the central region) is a result of the Si shrinkage following ion beam exposure. The density increase happens when single crystals are exposed to low dose ion implants, which causes small pockets (voids) to be generated and collapse within itself. However, during a 30 keV Xe⁺ implantation, the ions average penetration depth in silicon is equal to 21.02 nm, which generates a top amorphous layer (also referred to as a surface layer) with a 13.98 nm crystalline layer underneath (also referred to as a subsurface layer), therefore turning the implanted region into a bi-material. Since the implanted region shrinks, it causes a downward bowing of the bi-material (it would bend if not constrained), in a similar fashion to a bimetallic thermocouple strip. The energy of the ion implantation can be controlled to change the average penetration depth. The extra strain introduced by the bi-material bowing can therefore be precisely controlled by varying the ion implantation energy. The maximum bowing effect and therefore maximum strain is generated when the surface layer and subsurface layer are of equal thickness.

### EXAMPLE 2: TENSIONING A BUCKLED SI THIN FILM

The example shown in FIG. 2 illustrate how different exposure patterns can cause different effects on the silicon thin film. By exposing an annulus around the crystalline area to a dose of 3.75×10¹⁴ Xe⁺ ion cm² (FIG. 2a) it is possible to create a wrinkles free crystalline area at the centre like in the Example 1. However, another circle exposure at the centre of the large flat crystalline area generates a tensile strain happening radially to the new crystalline annulus just created (FIG. 2b). By increasing the dose in which the inner circle is exposed to the ion beam (1.88×10¹⁴ ions cm⁻² s⁻¹) more tensile strain is generated to further compression of the amorphised top layer.

This bowing of the exposed parts of the membrane does not have a considerable curvature (when it is restrained) besides being amorphous, and therefore cannot be easily detected using scanning electron microscopes (SEM) or atomic force microscopes (AFM). However, a bowing caused by the bilayer structure is implied by the manifestation of wrinkles such as from a liquid droplet placed on a thin elastic film, which creates a bowing of membrane underneath the droplet followed by the appearance of radial wrinkles.^{10,11} Similarly, ion beam exposure of a circle at the centre of the membrane window forms radial wrinkles due to the bowing resulting from bilayer formation, as can be seen in FIG. 2. By doing so, one can not only annihilate wrinkles but also re-pattern them on demand based on the exposure pattern and dose.

### EXAMPLE 3: BIAXIAL STRAIN ENGINEERING

The inventors investigated the degree of biaxial strain produced by controlling the ratio of the areas of the tensioner (exposed region) to that of the tympanum (central single-crystal). The magnitude of the strain was estimated from the shift of the 521 cm⁻¹ peak (T_{2g} mode) in the Raman spectrum.

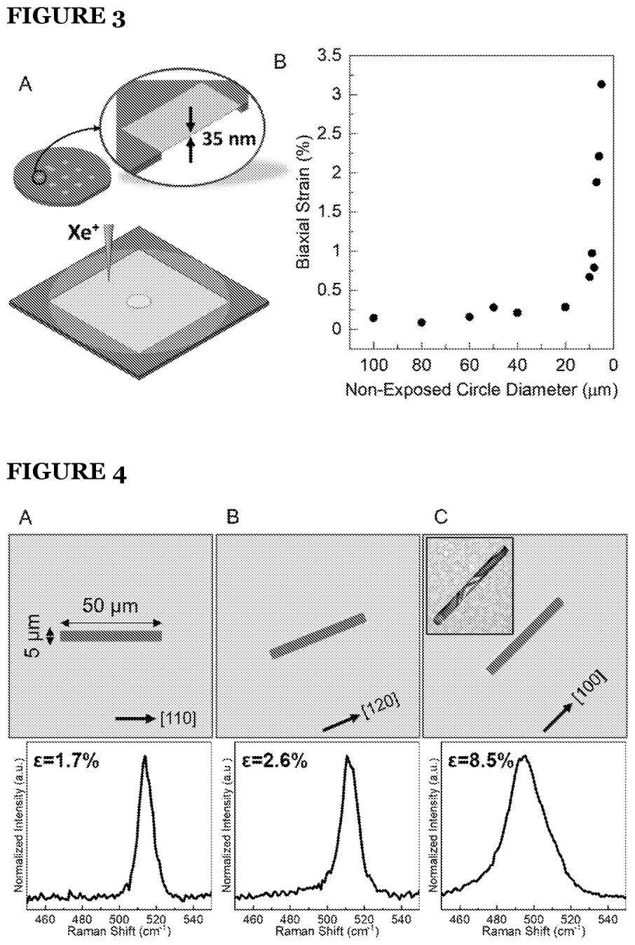

The effect of the exposed and non-exposed ratio on the resulting Raman shift of the T_{2g} peak and, therefore, stress was investigated by using different annulus patterns. These patterns were created prior to the ion implantation. The annulus consisted of two concentric circles in which a smaller diameter one was subtracted from the larger diameter circle, and as a result the smaller circle was not exposed to the ion beam (a schematic drawing can be found in FIG. 3a).

Previous experiments of Raman shift vs applied compressive biaxial stress using silicon films on sapphire substrate reported a relationship between stress (σₓₓ=σ_{yy}) and Raman shift (Δωₛ) equal to σₓₓ=σ_{yy}=−249 MPa·Δωₛ. Other studies using standard SOI or SOI formed by high dose oxygen ion implantation showed almost the same relationship, in which the in-plane stress was obtained from the Raman spectrum using the following relationship: σₓₓ=σ_{yy}=−250 MPa·Δωₛ. The inventors note that in germanium it has been found that the conversion is non-linear at high stress although no such non-linearity has been reported for silicon. The inventors take these linear conversions to apply for biaxial tensile stress used here which shifts the peak to lower frequencies (red shift) so that for biaxial tension the relationship between strain % (ε) and Raman shift (Δωₛ) is equal to 0.121 cm*Δωₛ cm⁻¹:¹²⁻²⁰

The diameter of the tympanum (the inner circle crystalline area) was varied from d=100 μm to d=5 μm. The obtained biaxial strain with different annulus size exposures can be found in FIG. 3b. One should note that the membrane windows edge size range between 100-120 μm and, therefore, the reported strain should change slightly since larger exposed areas cause a bigger shrinkage/downward bending. The inventors stopped the inner circle diameter at this point only because further reduction in d would bring it below the spatial resolution of the Raman microscope. At the highest value of d the tension is already enough to provide a flat tympanum. It is clear from FIG. 3b that the strain can be smoothly increased from small values up to very high biaxial strain. This strain enhancement with increasing exposed to non-exposed area is a consequence of the smaller separation of the tensioner edges when it is bowed, therefore by having one edge restrained by the frame and the other attached to the tympanum, the bowing amplifies the stress when compared to when it is flat.

### EXAMPLE 4: UNIAXIAL STRAIN ENGINEERING

To investigate uniaxial strain the inventors produced tympana in high aspect ratio slot shapes. For such tympana, the stress and strain in the centre is dominated by the uniaxial forces perpendicular to the long edges, and other components only appear near the ends. To explore the influence of the crystal anisotropy on the induced strain, 50 μm×5 μm rectangular tympana were positioned aligned to three different silicon orientations: [110] (when at 0°), [100] (when at 45°), and in-between when at 22.5°. As the angle between the orientation of the tympanum and the [110] direction is increased, a higher Raman red shift of the main peak is observed, FIG. 4, which is accompanied by an increase of the FWHM. The Raman shifts correspond to strains of 1.7% to 8.5% for the [110] and [100] orientations, respectively, with corresponding FWHM of 7.5 cm⁻¹ to 22.6 cm⁻¹. The intermediate tympanum angle at 22.5° presents a strain of 2.6% and a FWHM of 9.7 cm⁻¹.

The pulling force applied to the crystalline area is proportional to the length between the edges of the silicon membrane window and the respective slot. Additionally, the stiffness (resistance to deformation) is proportional to the Young's modulus.²¹ Thus, considering that diagonals are the longest length and that Young's modulus is lower in the silicon [100] direction (130.2 GPa), it is expected a higher stress at the centre of the slot oriented at 45°, i.e, the [100] direction offers less resistance to the bending of exposed area and, therefore, applies a higher pulling force on the 450 oriented slot. On the other hand, the exposed distance is minimum when the slot is at 0° as well as the [110] Young's modulus has its maximum value at this direction (168.9 GPa).²² Furthermore, when the slot is positioned at 45°, one can consider the largest force being applied in a direction normal to the slot larger edge, preventing the force to be decreased by a factor of sin(θ).

### EXAMPLE 5: EFFECT OF THE ASPECT RATIO ON THE RESULTING STRESS

To close the loop regarding the influence of width on the membrane strain and the effect of defect quantity on the FWHM of the main peak observed on the Raman spectra, samples were prepared containing slots of different aspect ratios oriented at 450 ([100] direction).

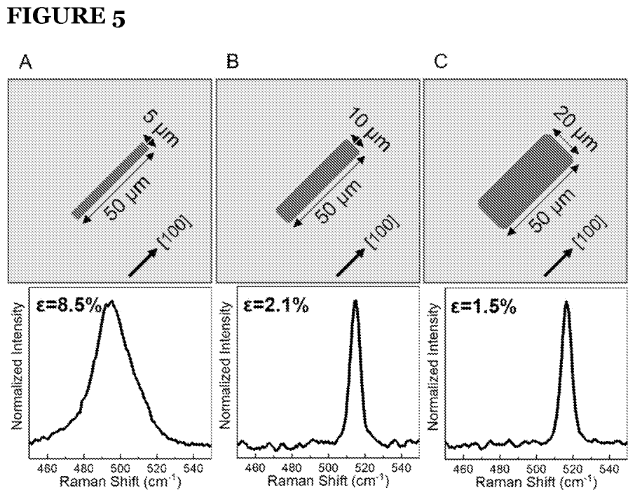

By inspecting FIG. 5, one can notice a considerable leap between the 50 μm×10 m and the 50 μm×5 μm slot, as observed for the 10 μm and 5 μm circles in FIG. 3. When Xe⁺ ions were implanted around 20 μm, 10 μm, and 5 μm diameter circles, peaks at 518.66°, 515.45°, and 500.85° were obtained. On the other hand, for the 50 μm×20 m, 50 μm×10 μm, and 50 μm×5 μm slots, peaks at 516.50 cm⁻¹, 514.70 cm⁻¹, and 495.40 cm⁻¹ were found. These findings not only show the major role played by the crystalline area width, but also endorse the idea that exploring the silicon anisotropy in order to get the strongest force oriented normal to the slot edge and parallel to the direction of the lowest Young's modulus ([100]) results in a bigger shift of the silicon main peak and, therefore, in a higher strain. A clear example proving the last statement is the fact that a 50 μm×20 μm slot is considered more strained regarding the original membrane, whereas the 20 μm circle is taken as a relaxed membrane (with its peak closer to 521 cm⁻¹ expected for bulk silicon).

It is also noteworthy that a higher FWHM was obtained for the 50 μm×5 μm slots when compared to the 5 μm circle (22.6 cm⁻¹ versus 17.9 cm⁻¹). Hence, considering that the chances of having implanted ions inside the 5 μm circle are higher than in a 125×5 μm slot, once again the inventors can correlate the peak broadening with the resulting strain on the crystalline area, instead of the gaussian distribution of implanted ions around the pattern edge.

### EXAMPLE 6: IMPLANTING IONS IN A GERMANIUM MEMBRANE

The inventors prepared a germanium membrane and implanted it with ions in a manner analogous to that described in example 1. The inventors note that, qualitatively, the resultant structure appears to behave the same way as the implanted silicon membranes. The inventors expect that once they conduct qualitative analysis this will back up their initial qualitative observations.

### REFERENCES

1. Uchida, K., Kinoshita, A. & Saitoh, M. Carrier transport in (110) nMOSFETs: Subband structures, non-parabolicity, mobility characteristics, and uniaxial stress engineering. in 2006 International Electron Devices Meeting 1-3 (IEEE, 2006).
2. Lee, W., Hwangbo, Y., Kim, J.-H. & Ahn, J.-H. Mobility enhancement of strained Si transistors by transfer printing on plastic substrates. NPG Asia Mater. 8, e256 (2016).
3. Paul, D. J. Si/SiGe heterostructures: from material and physics to devices and circuits. Semicond. Sci. Technol. 19, R75 (2004).
4. Whall, T. E. & Parker, E. H. C. SiGe-heterostructures for CMOS technology. Thin Solid Films 367, 250-259 (2000).
5. Geiger, R. et al. Uniaxially stressed germanium with fundamental direct band gap. arXiv Prepr. arXiv1603.03454 (2015).
6. Jansen, H., Gardeniers, H., de Boer, M., Elwenspoek, M. & Fluitman, J. A survey on the reactive ion etching of silicon in microtechnology. J. micromechanics microengineering 6, 14 (1996).
7. Brunner, K., Abstreiter, G., Kolbesen, B. O. & Meul, H. W. Strain at Si□ SiO₂ interfaces studied by Micron-Raman spectroscopy. Appl. Surf. Sci. 39, 116-126 (1989).
8. Jaccodine, R. J. & Schlegel, W. A. Measurement of strains at Si—SiO₂ interface. J. Appl. Phys. 37, 2429-2434 (1966).
9. Taraschi, G., Pitera, A. J. & Fitzgerald, E. A. Strained Si, SiGe, and Ge on-insulator: review of wafer bonding fabrication techniques. Solid. State. Electron. 48, 1297-1305 (2004).
10. Davidovitch, B. & Vella, D. Partial wetting of thin solid sheets under tension. Soft Matter 14, 4913-4934 (2018).
11. Box, F. et al. Dynamics of wrinkling in ultrathin elastic sheets. Proc. Natl. Acad. Sci. 116, 20875-20880 (2019).
12. Ganesan, S., Maradudin, A. A. & Oitmaa, J. A lattice theory of morphic effects in crystals of the diamond structure. Ann. Phys. (N. Y). 56, 556-594 (1970).
13. Anastassakis, E., Cantarero, A. & Cardona, M. Piezo-Raman measurements and anharmonic parameters in silicon and diamond. Phys. Rev. B 41, 7529 (1990).
14. Anastassakis, E., Pinczuk, A., Burstein, E., Pollak, F. H. & Cardona, M. Effect of static uniaxial stress on the Raman spectrum of silicon. Solid State Commun. 88, 1053-1058 (1993).
15. De Wolf, I. Micro-Raman spectroscopy to study local mechanical stress in silicon integrated circuits. Semicond. Sci. Technol. 11, 139 (1996).
16. Macia, J. et al. Raman microstructural analysis of silicon-on-insulator formed by high dose oxygen ion implantation: As-implanted structures. J. Appl. Phys. 82, 3730-3735 (1997).
17. Wolf, I. De. Stress measurements in Si microelectronics devices using Raman spectroscopy. J. Raman Spectrosc. 30, 877-883 (1999).
18. de Wolf, I. Finding the Stress from the Raman Shifts: A Case Study. in Raman Scattering in Materials Science 104-106 (Springer, 2000).
19. Peng, C.-Y. et al. Comprehensive study of the Raman shifts of strained silicon and germanium. J. Appl. Phys. 105, 83537 (2009).
20. Urena, F., Olsen, S. H. & Raskin, J.-P. Raman measurements of uniaxial strain in silicon nanostructures. J. Appl. Phys. 114, 144507 (2013).
21. Baumgart, F. Stiffness—an unknown world of mechanical science? Inj. J. Care Inj. 31, 14-23 (2000).
22. Kim, J., Cho, D. D. & Muller, R. S. Why is (111) silicon a better mechanical material for MEMS? in Transducers' 01 Eurosensors XV662-665 (Springer, 2001).

1. A semiconductor structure comprising:
a semiconductor membrane, wherein the semiconductor membrane has at least one amorphised area and an active area, wherein the at least one amorphised area is adjacent the active area such that the at least one amorphised area exerts strain on the active area,
wherein the semiconductor membrane comprises a surface layer and a subsurface layer, wherein the surface layer comprises the active area and the at least one amorphised area, and the subsurface layer is crystalline, such that the semiconductor membrane exhibits bi-material bowing where the semiconductor membrane has been amorphised.

2. (canceled)

3. A semiconductor structure according to claim 1, wherein the thickness of the surface layer is between 40 and 60% of the thickness of the semiconductor membrane.

4. A semiconductor structure according to claim 1, wherein the active area surrounds a first amorphised area.

5. A semiconductor structure according to claim 4, wherein the first amorphised area has a circular shape or an elongated shape.

6. A semiconductor structure according to claim 1, wherein the at least one amorphised area surrounds a first active area.

7. A semiconductor structure according to claim 6, wherein the at least one amorphised area comprises an annulus and wherein the first active area is located in the centre of the annulus.

8. A semiconductor structure according to claim 6, wherein the active area has an elongated shape.

9. A semiconductor structure according to claim 8, wherein the elongate shape defines an aspect ratio of between 150:1 and 2:1, between 100:1 and 3:1 or between 75:1 and 4:1.

10. A semiconductor structure according to claim 6, wherein The ratio between the maximum width of the amorphised area and the maximum width of the first active area is between 1:50 and 200:1, between 1:25 and 100:1, between 1:10 and 75:1, between 1:5 and 50:1, between 1:1 and 40:1, between 2:1 and 30:1 or between 5:1 and 20:1.

11. A semiconductor structure according to claim 1, wherein the semiconductor membrane has a plurality of active areas.

12. A semiconductor structure according to claim 1, wherein the active area defines a crystalline structure.

13. A semiconductor structure according to claim 12, wherein the crystalline structure is orientated such that anisotropy is exhibited in the surface plane of the active area of the crystalline structure.

14. A semiconductor structure according to claim 1, wherein the semiconductor membrane comprises or consists of a group IV element, a Ill-V compound semiconductor or a group IV alloy.

15. A semiconductor structure according to claim 14, wherein the semiconductor membrane comprises or consists of silicon, germanium, silicon-germanium, doped silicon or doped germanium.

16. A semiconductor device, an optical amplifier or an optoelectronic device comprising the semiconductor structure of claim 1.

17. A method of introducing strain into a crystalline semiconductor membrane comprising:
providing a crystalline semiconductor membrane,
defining at least one implantation area and an active area adjacent the at least one implantation area on the surface of the semiconductor membrane, and
implanting ions into the at least one implantation area of the semiconductor membrane such that the semiconductor membrane becomes amorphised in the at least one implantation area causing the semiconductor membrane to exhibit bi-material bowing where the semiconductor membrane has been amorphised and causing strain in the active area.

18. The method of claim 17, wherein implanting ions comprises implanting noble gas ions.

19. The method of claim 18, wherein implanting ions comprises implanting Xenon ions

20. The method of claim 17, wherein providing the crystalline semiconductor membrane comprises providing a single-crystal membrane.

21. The method of claim 17, wherein the method comprises implanting ions into the at least one implantation area to a depth of between 40 and 60% of the thickness of the semiconductor membrane.
